(19) United States
(12) Patent Application Publication
(10) Pub. No.: US 2026/0247689 A1
(43) Pub. Date: Aug. 20, 2026

(54) GATE ISOLATION FEATURE IN CFET DEVICES

(71) Applicant: Taiwan Semiconductor Manufacturing Company, Ltd., Hsin-Chu (TW)

(72) Inventors: Szu-Hua Chen, Tainan City (TW); Wei-Xiang You, Kaohsiung City (TW); Wei-Yen Woon, Taoyuan City (TW); Szuya Liao, Zhubei (TW)

(21) Appl. No.: 19/054,202

(22) Filed: Feb. 14, 2025

(51) Int. Cl. H10D 84/01; H10D 84/85

(52) U.S. Cl. CPC H10D 84/0188; H10D 84/851; H10D 84/854

(57) ABSTRACT

A method of forming a semiconductor device includes forming a structure having a bottom region and a top region, the bottom region having a first plurality of channels for forming a first type transistor, the top region having a second plurality of channels for forming a second type transistor, where the top and the bottom regions are separated by a channel isolation layer; depositing a first gate metal over the structure and wrapping around each channel of the first and the second plurality of channels; etching back the first gate metal to expose each channel of the second plurality of channels; depositing a gate isolation layer on the etched-back first gate metal, where the gate isolation layer has a dielectric constant lower than 7; and depositing a second gate metal on the gate isolation layer and wrapping around each channel of the second plurality of channels.

### BACKGROUND

The present disclosure relates to an integrated circuit (IC) structure and a method of making the same. Especially, the IC structure includes a transistor structure having multiple vertically stacked gate-all-around transistors, each of which includes multiple vertically stacked nanowires or nanosheets as channels. More specifically, the IC structure includes a complementary field-effect transistor (CFET) structure and the method of making the CFET. The CFET may include N-type FETs vertically over P-type FETs or P-type FETs vertically over the N-type FET.

In advanced technologies such as CFETS, various isolation features are needed to properly isolate the vertically stacked N-type and P-type FETs. For example, various isolation features are used to isolate N-type and P-type source/drain features and/or semiconductor channels of the N-type and P-type FETs from each other. In some cases, the N-type and P-type FETs share a same gate contact, and a continuous CFET gate metal is deposited over channels of the stacked N-type and the P-type FETs. In other cases, the N-type and P-type FETs do not have a shared gate contact, and there requires gate isolation features to separate the gate of the N-type FETs from the gate of the P-type FETs. In these cases, due to critical dimension scaling, there exists risks of current leakage and/or high capacitive coupling between separate gates.

Therefore, while existing gate isolation features in CFET devices are generally adequate for their intended purposes, they are not satisfactory in all aspects.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments. Further, the accompanying figures may implicitly describe features not explicitly described in the detailed description.

FIGS. 1A-1B illustrate a flow chart of a method to form a CFET semiconductor device having a gate isolation feature, in portion or in entirety, according to an embodiment of the present disclosure.

FIGS. 2-9, 10A, 10B, 11A, 11B, 12A, 12B, 13A, and 13B illustrate cross-sectional views of a CFET semiconductor device having a gate isolation feature, at intermediate stages of fabrication and processed in accordance with the method of FIGS. 1A-1B, according to an embodiment of the present disclosure.

FIGS. 14A-14C illustrate various views of a device isolation layer vertically disposed between an NFET and a PFET of a CFET semiconductor device.

FIG. 15 illustrates a flow chart of a method to form a CFET semiconductor device having a gate isolation feature, in portion or in entirety, according to another embodiment of the present disclosure.

FIGS. 16-20 illustrate cross-sectional views of a CFET semiconductor device having a gate isolation feature, at intermediate stages of fabrication and processed in accordance with the method of FIG. 15, according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “under,” “below,” “lower,” “above,” “over,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” “substantially,” and the like, the term is intended to encompass numbers that are within a reasonable range including the number described, such as within +/−10% of the number described, or other values as understood by person skilled in the art. For example, the term “about 5 nm” may encompass the dimension range from 4.5 nm to 5.5 nm where manufacturing tolerances associated with depositing the material layer are known to be +/−10% by one of ordinary skill in the art. And when comparing a dimension or size of a feature to another feature, the phrases “substantially the same,” “essentially the same,” “of similar size,” or the like, may be understood to be within +/−10% between the compared features. Further, disclosed dimensions of the different features can implicitly disclose dimension ratios between the different features.

The present disclosure relates to CFET semiconductor devices having vertically stacked NFET and PFET devices. More specifically, the present disclosure describes various isolation features that isolate the NFET device from the PFET device, including between channels of the NFET and PFET device, between source/drains of the NFET and PFET device, and between gates of the NFET and PFET device.

To improve gate isolation and prevent high capacitive coupling between the gates of the NFET and PFET devices, a low-k gate isolation layer is formed at an interface between the NFET gate and the PFET gate. The low-k gate isolation layer is selected to be robust, thermally conductive, and electrically insulating. For example, the isolation layer includes boron nitride, which has a low dielectric constant for reducing capacitive coupling. Boron nitride is more robust than certain other low-k materials (e.g., oxide-based dielectrics that causes metal interdiffusion issues). Boron nitride also have the advantage having a low growth temperature on metal gates. In further examples, the isolation layer includes a crystalline ring-structure for high thermal conductivity (e.g., hexagonal boron nitride). The present disclosure contemplates selectively forming the low-k gate isolation layer in a CFET structure according to design needs. The present disclosure also contemplates forming varied device isolation features (e.g., channel isolation, source/drain isolation, etc.) for holistic isolation between top and bottom FETs of a CFET structure.

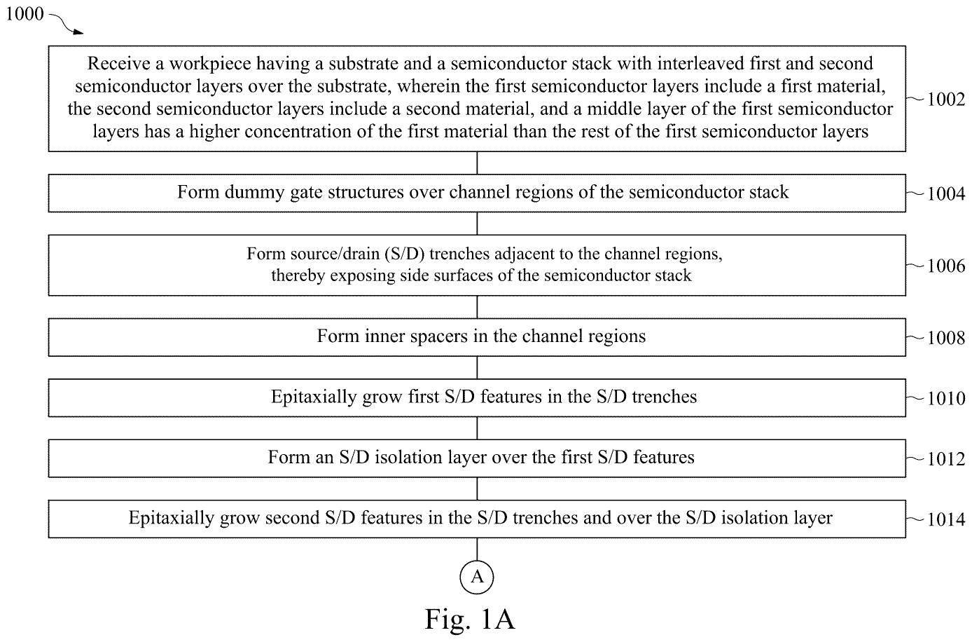

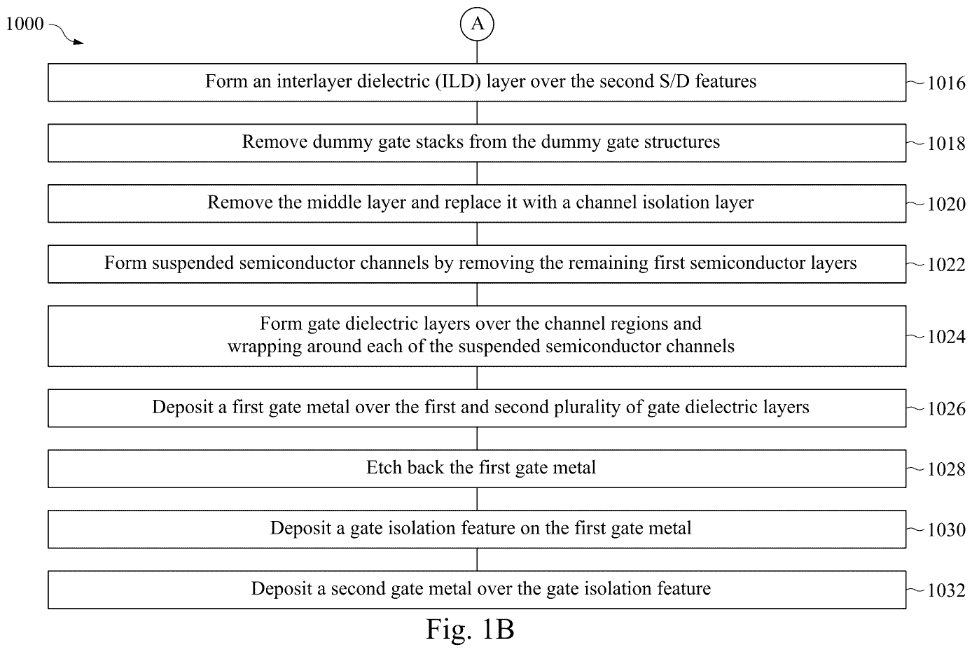

FIGS. 1A-1B is a flow chart of a method 1000 to form a CFET semiconductor device 100 having a gate isolation feature 514, in portion or in entirety, according to an embodiment of the present disclosure. The device 100 may be a portion of an integrated circuit (IC) chip, a system on chip (SoC), or portion thereof, that includes various passive and active microelectronic devices such as resistors, capacitors, inductors, diodes, p-type field effect transistors (PFETs), n-type field effect transistors (NFETs), FinFET, nanosheet FETs, nanowire FETs, other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, other suitable components, or combinations thereof. In some embodiments, the device is included in a non-volatile memory, such as a non-volatile random access memory (NVRAM), a flash memory, an electrically erasable programmable read only memory (EEPROM), an electrically programmable read-only memory (EPROM), other suitable memory type, or combinations thereof.

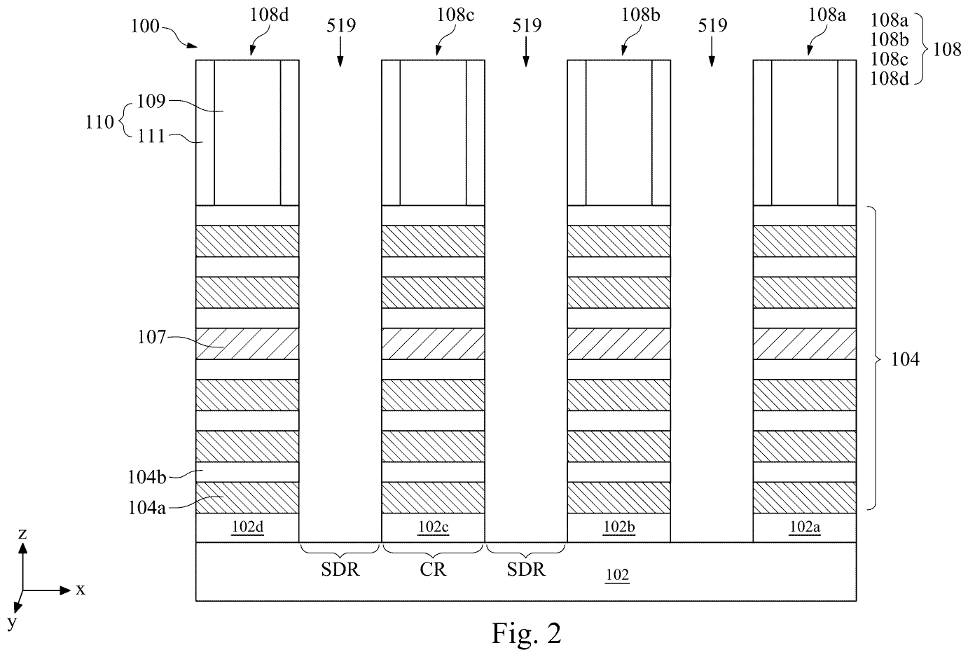

FIGS. 2-9, 10A, 10B, 11A, 11B, 12A, 12B, 13A, and 13B illustrate cross-sectional views of a CFET semiconductor device 100 having a gate isolation feature 514, at intermediate stages of fabrication and processed in accordance with the method 1000 of FIGS. 1A-1B, according to an embodiment of the present disclosure. The method 1000 is described below with reference to FIGS. 2-9, 10A, 10B, 11A, 11B, 12A, 12B, 13A, and 13B.

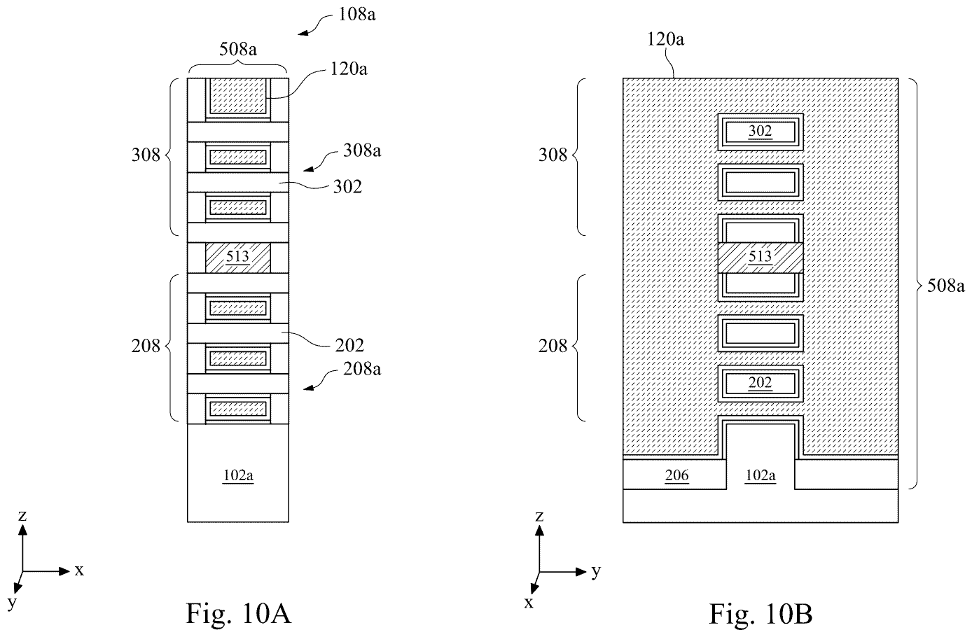

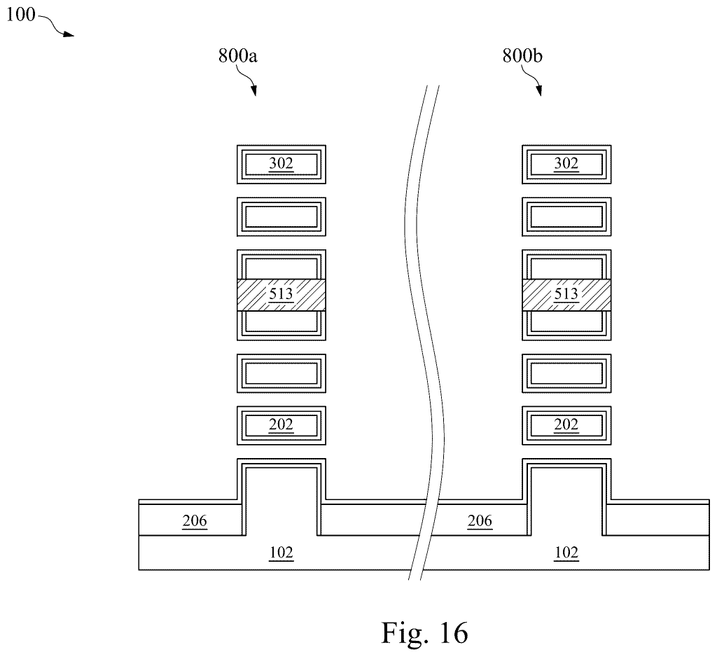

Referring to FIG. 2, the method 1000 at operation 1002 receives or is provided with a workpiece having a substrate 102 and a semiconductor stack 104 with interleaved first and second semiconductor layers 104a and 104b over the substrate 102. The substrate 102 may be a silicon (Si) substrate, or a substrate having other semiconductor materials such as germanium (Ge), silicon carbide (SiC), silicon germanium (SiGe), or diamond. The semiconductor stack 104 may also be referred to as active regions that extend lengthwise along the x direction. Additional semiconductor stacks 104 may be formed in parallel along the y direction, and the semiconductor stacks 104 are separated from each other by an isolation structure such as a shallow trench isolation (STI) structure (e.g., see isolation structure 206 in FIGS. 10B and 16).

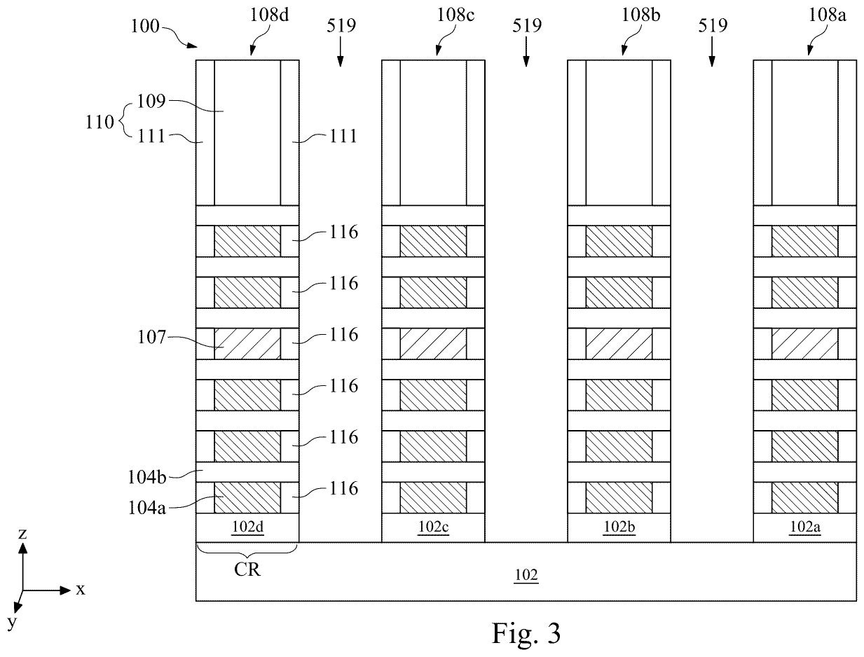

The first semiconductor layers 104a have a different material composition than the second semiconductor layers 104b to achieve etch selectivity. For example, each of the first semiconductor layers 104a is made of silicon germanium and each of the second semiconductor layers 104b is made of silicon. Note that the first semiconductor layers 104a include a middle layer 107 that has a different concentration makeup than the rest of the first semiconductor layers 104a. For example, the middle layer 107 is made of silicon germanium but has a greater concentration of germanium than the rest of the first semiconductor layers 104a. In furtherance of the example, the first semiconductor layers 104a are SiGe layers with germanium concentration ranging between 20% and 25% (atomic percentage), and the middle layer 107 is a silicon germanium layer with germanium concentration greater than 30% (atomic percentage), such as ranging between 40% and 60%. This allows for selective etching of the middle layer 107 in a later process step, where the middle layer 107 is replaced with a channel isolation layer to separate a top device from a bottom device of the CFET device 100. Note that the middle layer 107 does not necessarily have to be in the exact middle to separate a top device from a bottom device. This layer may be closer to the top of the stack or closer to the bottom of the stack, and as such, it is possible that the bottom device will have more or less semiconductor channels than the top device. In an embodiment shown in FIG. 3, the first semiconductor layers 104a include a first material (i.e., germanium), the second semiconductor layers 104b include a second material (i.e., silicon), and a middle layer 107 of the first semiconductor layers 104a has a higher concentration of the first material (i.e., germanium) than the rest of the first semiconductor layers 104a. The second semiconductor layers 104b may be of a same material composition as the substrate 102.

Still referring to FIG. 2, the method 1000 at operation 1004 forms dummy gate structures 110 over channel regions CR of the semiconductor stack 104. The channel regions CR include channel regions 102a-102d that are part of the substrate 102. The dummy gate structures 110 define various CFET gate regions 108. For example, the CFET gate regions may include CFET gate regions 108a, 108b, 108c, and 108d. Each of the dummy gate structures 110 includes a dummy gate stack 109 and gate spacers 111 over sidewalls of the dummy gate stack 109. The dummy gate stack 109 may be made of polysilicon and the gate spacers 111 may be made of silicon oxide, silicon nitride, silicon oxycarbide, silicon oxycarbonitride, silicon carbonitride, metal nitride, or a suitable dielectric material.

Still referring to FIG. 2, the method 1000 at operation 1006 forms source/drain (S/D) trenches 519 in S/D regions SDR adjacent to the channel regions CR, thereby exposing side surfaces of the semiconductor stack 104. The S/D trenches 519 may be formed by a dry etching process, a wet etching process, other suitable etching process, or combinations thereof. In some embodiments, the etching process is a multi-step etch process. For example, the etching process may include alternative etchants to separately and alternately remove first semiconductor layers 104a and semiconductor layers 104b. In some embodiments, parameters of the etching process are configured to selectively etch the semiconductor stack 104 with minimal (to no) etching of dummy gate structures 110 (i.e., dummy gate stacks 109 and gate spacers 111). In some embodiments, a lithography process is performed to form a patterned mask layer that covers dummy gate structures 110 and/or portions of an isolation structure between semiconductor stacks 104, and the etching process uses the patterned mask layer as an etch mask when forming the S/D trenches 519. Note that the etching process may also etch slightly into the substrate 102. That is, when forming the S/D trenches 519, the substrate 102 may be recessed to form protruding portions that define the channel regions 102a, 102b, 102c, and 102d.

Now referring to FIG. 3, the method 1000 at operation 1008 forms inner spacers 116 in the channel regions CR along sidewalls of the first semiconductor layers 104a by any suitable process. For example, a side etch process is first performed to selectively etch sidewalls of the first semiconductor layers 104a without etching (or substantially etching) the second semiconductor layers 104b. In other words, the side etch process is configured to laterally etch (e.g., along the x direction) first semiconductor layers 104a, thereby reducing a length of first semiconductor layers 104a along the x direction. The side etch process is a dry etching process, a wet etching process, other suitable etching process, or combinations thereof. After the side etch process is performed, air gaps are formed under each of the second semiconductor layers 104b. Then, as shown in FIG. 3, inner spacers 116 are formed in each of the air gaps. The inner spacers 116 are disposed directly below the gate spacers 111, and they may be substantially vertically aligned with the gate spacers 111 along the z direction.

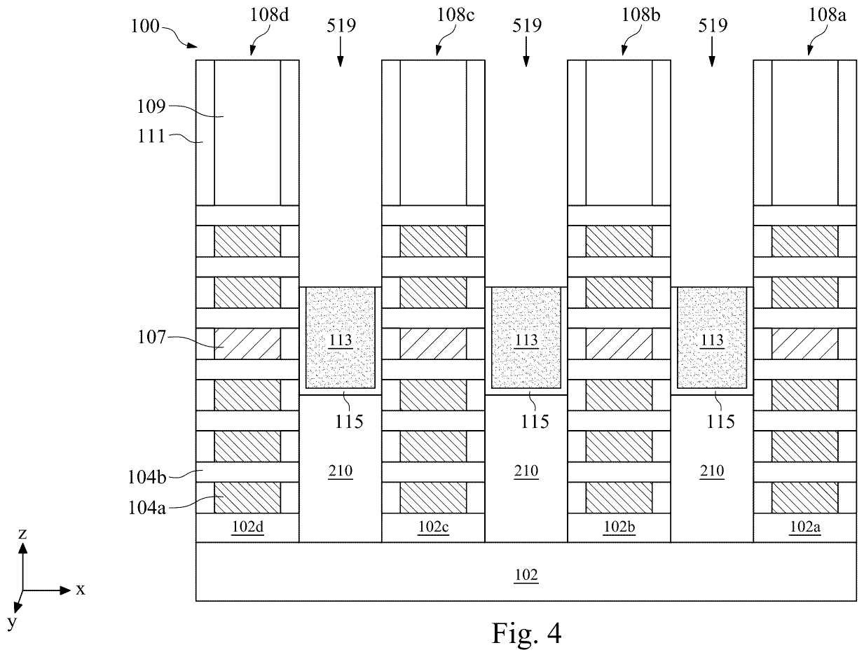

The inner spacers 116 may be formed by a spacer deposition process and a spacer etching process. For example, a spacer deposition process is performed to form a spacer layer over the dummy gate structures 110 and over features defining the S/D trenches 519 (e.g., semiconductor layers 104a, semiconductor layers 104b, and substrate 102). The spacer deposition process may include processes such as CVD, PVD, ALD, HDPCVD, MOCVD, RPCVD, PECVD, LPCVD, ALCVD, APCVD, plating, other suitable methods, or combinations thereof. The spacer layer partially (and, in some embodiments, completely) fills the S/D trenches 519. The spacer deposition process is configured to ensure that the spacer layer fills the air gaps between semiconductor layers 104b and between semiconductor layers 104b and the respective channel regions 102a-102d under gate spacers 111. A spacer etching process is then performed that selectively etches the spacer layer to form inner spacers 116 as depicted in FIG. 4 with minimal (to no) etching of semiconductor layers 104b, dummy gate stacks 109, and gate spacers 111. In the disclosed embodiment, the spacer etching process includes an anisotropic etching, such as plasma etch. The spacer layer (and thus inner spacers 116) includes a material that is different than a material of semiconductor layers 104b and a material of gate spacers 111 to achieve desired etching selectivity during the gate spacer etching process. In some embodiments, the spacer layer includes a dielectric material that includes silicon, oxygen, carbon, nitrogen, other suitable material, or combinations thereof (for example, silicon oxide, silicon nitride, silicon oxynitride, silicon carbide, or silicon oxycarbonitride).

Now referring to FIG. 4, the method 1000 at operation 1010 epitaxially grows first S/D features 210 in the S/D trenches 519 for bottom transistor devices of the CFET device 100. The bottom transistor devices may be NFET transistor devices or PFET transistor devices. As such, the first source/drain features 210 may include n-type source/drain features that correspond with n-type transistor regions or p-type source/drain features that correspond with p-type transistor regions. The first source/drain features 210 may be formed by an epitaxy process using CVD deposition techniques (for example, VPE and/or UHV-CVD), molecular beam epitaxy, other suitable epitaxial growth processes, or combinations thereof. The epitaxy process can use gaseous and/or liquid precursors, which interact with the composition of substrate 102 and/or semiconductor stacks 104 (in particular, semiconductor layers 104b). Epitaxial source/drain features are doped with n-type dopants and/or p-type dopants. In some embodiments, for the n-type CFET transistors, first epitaxial source/drain features 210 include silicon and can be doped with phosphorous, arsenic, other n-type dopant, or combinations thereof (for example, forming Si:C epitaxial source/drain features, Si:P epitaxial source/drain features, or silicon carbon doped with phosphorus—SiC:P epitaxial source/drain features). In some embodiments, for the p-type CFET transistors, first epitaxial source/drain features 210 include silicon germanium or germanium and can be doped with boron, other p-type dopant, or combinations thereof (for example, forming Si:Ge:B epitaxial source/drain features). In the embodiment shown, the first S/D features 210 are p-type S/D features for PFET devices.

Still referring to FIG. 4, the first S/D features 210 only partially fill the S/D trenches 519. Specifically, they are grown (or grown and recessed) to a height below the middle layer 107 in the z direction. That is, the first S/D features 210 are in direct contact with semiconductor layers 104b for bottom transistor devices under the middle layer 107, but not the semiconductor layers 104b above the middle layer 107. Note that in some embodiments, like as shown, the first S/D features 210 need not be in direct contact with all the semiconductor layers 104b under the middle layer 107.

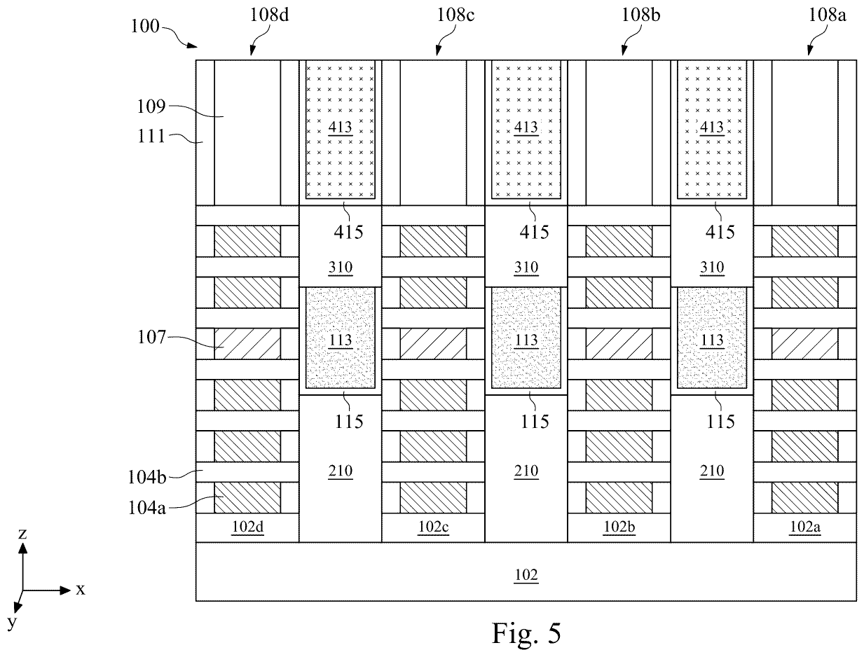

Still referring to FIG. 5, the method 1000 at operation 1012 forms an S/D isolation layer 113 over the first S/D features 210. This may be done by first conformably depositing a dielectric liner such as an etch stop layer 115 by CVD, ALD or other suitable processes, then depositing the S/D isolation layer 113 over the etch stop layer 115. An etch process may follow to recess top surfaces of the S/D isolation layer 113 and etch stop layer 115. In some embodiments, the operation 1012 includes depositing the etch stop layer 115 and the S/D isolation layer 113, performing a chemical mechanical polishing (CMP), and etching to recess the deposited materials. In some embodiments, the operation 1012 may apply a selective deposition. The etch stop layer 115 may include silicon nitride and the S/D isolation layer 113 may include a dielectric material that includes for example, silicon oxide, silicon nitride, silicon oxynitride, tetraethoxysilane (TEOS) formed oxide, Phosphosilicate Glass (PSG), Boron-Doped Phosphosilicate Glass (BPSG), low-k dielectric material, other suitable dielectric material, or combinations thereof. Exemplary low-k dielectric materials include silicon or polymer-based materials such as FSG, carbon doped silicon oxide, Black Diamond® (Applied Materials of Santa Clara, California), Xerogel, Aerogel, amorphous fluorinated carbon, Parylene, BCB, SiLK (Dow Chemical, Midland, Michigan), polyimide, or combinations thereof.

The S/D isolation layer 113 only partially fill the S/D trenches 519 since second S/D features 310 are to be formed over the S/D isolation layer 113. However, although only partially filled, the S/D isolation layer 113 should be thick enough to isolate the first S/D features 210 from the later formed second S/D features 310. As such, in some embodiments, like as shown, the S/D isolation layer 113 (or etch stop layer 115) may be in direct contact with sidewalls of the second semiconductor layers 104b, thereby isolating them from contacting the first or second S/D features 210 and 310. The S/D isolation layer 113 has a portion horizontally aligned with the middle layer 107 along the x direction. The S/D isolation layer 113 is separated from the middle layer 107 by inner spacers 116. In an embodiment, the S/D isolation layer 113 has a thickness in the z direction greater than a thickness of the middle layer 107.

Now referring to FIG. 5, the method 1000 at operation 1014 epitaxially grows second S/D features 310 in the S/D trenches 519 and over the S/D isolation layer 113 for top transistor devices of the CFET device 100. The top transistor devices may be NFET transistor devices or PFET transistor devices. As such, the second source/drain features 310 may include n-type source/drain features that correspond with n-type transistor regions or p-type source/drain features that correspond with p-type transistor regions. The second source/drain features 310 may be formed by an epitaxy process using CVD deposition techniques (for example, VPE and/or UHV-CVD), molecular beam epitaxy, other suitable epitaxial growth processes, or combinations thereof. The epitaxy process can use gaseous and/or liquid precursors, which interact with the composition of semiconductor stacks 104 (in particular, semiconductor layers 104b). Epitaxial source/drain features are doped with n-type dopants and/or p-type dopants. In some embodiments, for the n-type CFET transistors, second epitaxial source/drain features 310 include silicon and can be doped with phosphorous, arsenic, other n-type dopant, or combinations thereof (for example, forming Si:C epitaxial source/drain features, Si:P epitaxial source/drain features, or silicon carbon doped with phosphorus—SiC:P epitaxial source/drain features). In some embodiments, for the p-type CFET transistors, second epitaxial source/drain features 310 include silicon germanium or germanium and can be doped with boron, other p-type dopant, or combinations thereof (for example, forming Si:Ge:B epitaxial source/drain features). In the embodiment shown, the second S/D features 310 are n-type S/D features for NFET devices.

Still referring to FIG. 5, the second S/D features 310 may completely fill the S/D trenches 519 such that top surfaces of the second S/D features 310 are substantially coplanar with top surfaces of the topmost second semiconductor layers 104b. Alternatively, the second S/D features 310 may grow above the top surfaces of the topmost second semiconductor layers 104b. Note that the second S/D features 310 are in direct contact with semiconductor layers 104b for top transistor devices above the middle layer 107, but not the semiconductor layers 104b below the middle layer 107. Note that in some embodiments, like as shown, the second S/D features 310 need not be in direct contact with all the semiconductor layers 104b above the middle layer 107.

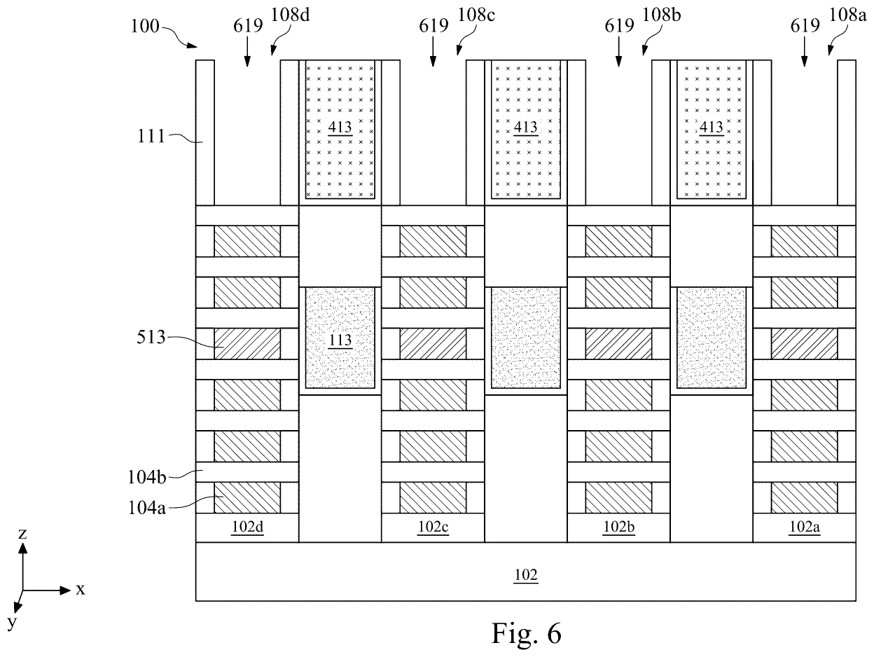

Still referring to FIG. 6, the method 1000 at operation 1016 forms an interlayer dielectric (ILD) layer 413 over the second S/D features 310. This may be done by first conformably depositing a dielectric liner such as an etch stop layer 415 by CVD, ALD or other suitable processes, then depositing the ILD layer 413 over the etch stop layer 415. A planarization process such as CMP may follow to planarize top surfaces of the ILD layer 413, etch stop layer 415, and dummy gate structures 110. The etch stop layer 415 may include silicon nitride and the ILD layer 413 may include a dielectric material that includes for example, silicon oxide, silicon nitride, silicon oxynitride, tetraethoxysilane (TEOS) formed oxide, Phosphosilicate Glass (PSG), Boron-Doped Phosphosilicate Glass (BPSG), low-k dielectric material, other suitable dielectric material, or combinations thereof. Exemplary low-k dielectric materials include silicon or polymer-based materials such as FSG, carbon doped silicon oxide, Black Diamond® (Applied Materials of Santa Clara, California), Xerogel, Aerogel, amorphous fluorinated carbon, Parylene, BCB, SiLK (Dow Chemical, Midland, Michigan), polyimide, or combinations thereof

Now referring to FIG. 6, the method 1000 at operation 1018 removes dummy gate stacks 109 from the dummy gate structures 110. The dummy gate stacks 109 are removed by a suitable etching process, thereby resulting in gate trenches 619 and exposing the semiconductor stacks 104. The etching process is designed with an etchant to selectively remove the dummy gate stacks 109. In the depicted embodiment, an etching process completely removes dummy gate stacks 109 to expose surfaces of the semiconductor layers 104a and semiconductor layers 104b in the x-z plane. The etching process is a dry etching process, a wet etching process, other suitable etching process, or combinations thereof. In some embodiments, the etching process is a multi-step etch process. For example, the etching process may include alternative etchants to separately remove various layers of dummy gate stacks 109, such as the dummy gate electrode layers, the dummy gate dielectric layers, and/or the hard mask layers. In some embodiments, the etching process is configured to selectively etch dummy gate stacks 109 with minimal (to no) etching of other features of the device 100, such as ILD layer 413, gate spacers 111, semiconductor layers 104a, and semiconductor layers 104b. In some embodiments, a lithography process is performed to form a patterned mask layer that covers the ILD layer 413 and/or gate spacers 111, and the etching process uses the patterned mask layer as an etch mask.

Still referring to FIG. 6, the method 1000 at operation 1020 removes the middle layer 107 and replaces it with a channel isolation layer 513. The middle layer 107 is removed by a suitable etching process. The etching process is designed with an etchant to selectively remove the middle layer 107. As described above, the middle layer 107 has a different concentration of materials such as heavier germanium concentration than other first semiconductor layers 104a (which also include germanium). This allows for selective etching of the middle layer 107 without etching the remaining semiconductor layers 104a. Thereafter, the air void that remains is filled with a dielectric material to form the channel isolation layer 513. The channel isolation layer 513 may include a dielectric material that includes silicon, oxygen, carbon, nitrogen, other suitable material, or combinations thereof (for example, silicon oxide, silicon nitride, silicon oxynitride, silicon carbide, or silicon oxycarbonitride). In some embodiments, the channel isolation layer 513 includes a low-k dielectric material. For example, the channel isolation layer 513 may include oxide derivatives such as fluorine-doped oxides, carbon-doped oxides, and/or hydrogen-doped oxides. For another example, the channel isolation layer 513 may include porous oxides such as xeorogels/aerogels. For another example, the channel isolation layer 513 may include organics such as polyimides, Teflon/PTFE, and/or other polymers. In some embodiments, the formation of the channel isolation layer 513 includes etching, deposition, and anisotropic etch, such as plasma etch.

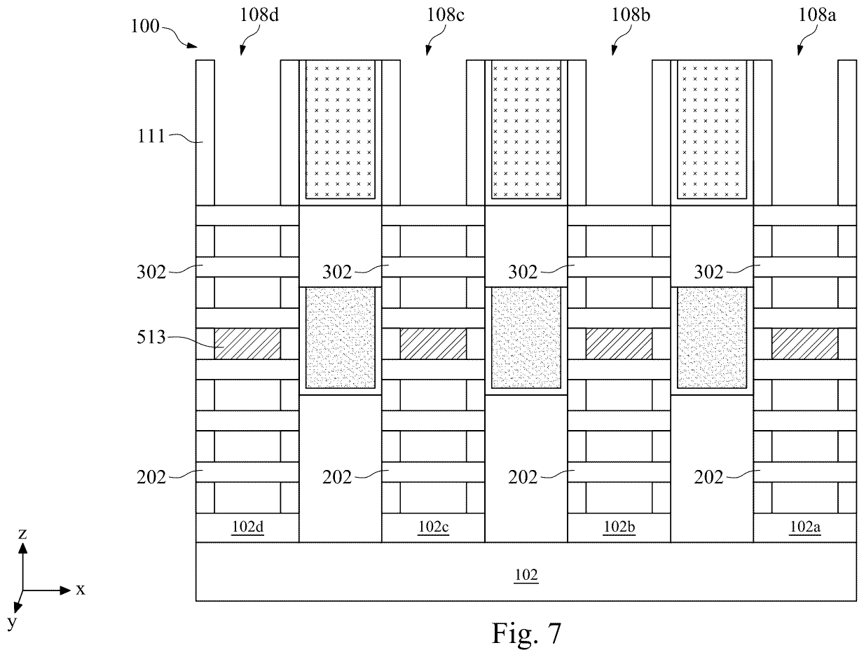

Now referring to FIG. 7, the method 1000 at operation 1022 forms suspended semiconductor channels 202/302 by removing the remaining first semiconductor layers 104a by a suitable etching process. The etching process is designed with an etchant to selectively remove the remaining first semiconductor layers 104a without substantially etching the second semiconductor layers 104b and the channel isolation layer 513. As such, the second semiconductor layers 104b become suspended semiconductor channels 202/302. The suspended semiconductor channels 202 refer to channel layers 202 for the bottom transistor devices (e.g., PFET channels of the CFET device 100) and the suspended semiconductor channels 302 refer to channel layers 302 for the top transistor devices (e.g., NFET channels of the CFET device 100).

With respect to selectively etching the middle layer 107 and selectively etching the first semiconductor layers 104a, various etching parameters can be tuned such as etchant composition, etching temperature, etching solution concentration, etching time, etching pressure, source power, RF bias voltage, RF bias power, etchant flow rate, other suitable etching parameters, or combinations thereof. For example, an etchant is selected to etch the material of the middle layer 107 (e.g., highest concentration of germanium) at a higher rate than the remaining semiconductor layers 104a (e.g., middle concentration of germanium). And an etchant is selected for the etching process that etches the semiconductor layers 104a (e.g., middle concentration of germanium) at a higher rate than the material of the semiconductor layers 104b (e.g., lowest concentration of germanium or no germanium). The etching process is a dry etching process, a wet etching process, other suitable etching process, or combinations thereof. In some embodiments, a dry etching process (such as an RIE process) utilizes a fluorine-containing gas (for example, SF6) to selectively etch the semiconductor layers. In some embodiments, a ratio of the fluorine-containing gas to an oxygen-containing gas (for example, O2), an etching temperature, and/or an RF power may be tuned to selectively etch silicon germanium (or silicon). In some embodiments, a wet etching process is performed with an etching solution that includes ammonium hydroxide (NH4OH) and water (H2O) to selectively etch the germanium-containing semiconductor layers. In some embodiments, a chemical vapor phase etching process using hydrochloric acid (HCl) is used.

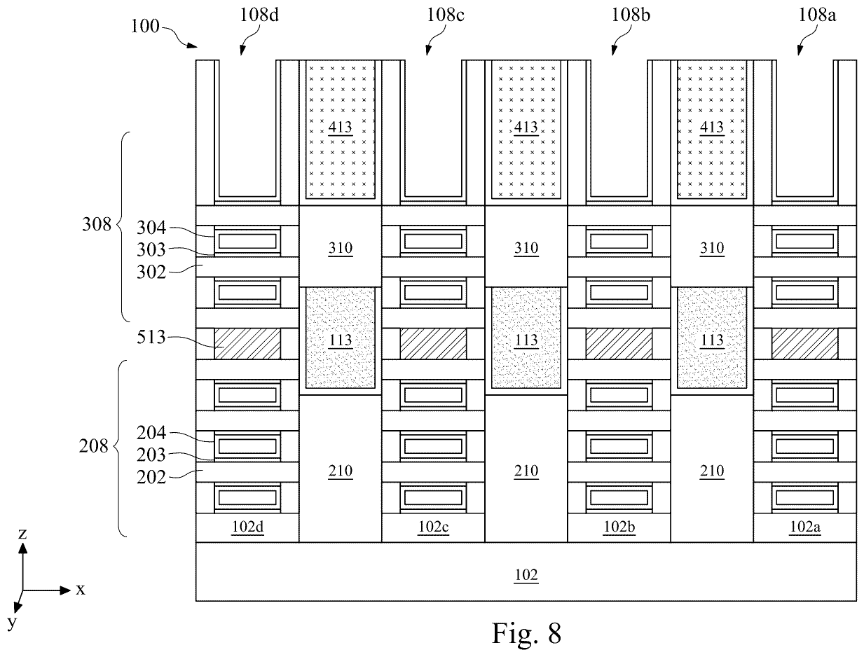

Now referring to FIG. 8, the method 1000 at operation 1024 forms gate dielectric layers 204/304 over the channel regions 102a-102d and wrapping around each of the suspended semiconductor channels 202/302. The gate dielectric layers 204/304 partially fills the gaps between the suspended semiconductor channels 202/302 and may include high-k dielectric materials such as HfO₂, HfSiO, HfSiO₄, HfSiON, HfLaO, HfTaO, HfTiO, HfZrO, HfAlOₓ, ZrO, ZrO₂, ZrSiO₂, AlO, AlSiO, Al₂O₃, TiO, TiO₂, LaO, LaSiO, Ta₂O₃, Ta₂O₅, Y₂O₃, SrTiO₃, BaZrO, BaTiO₃ (BTO), (Ba, Sr)TiO₃ (BST), Si₃N₄, hafnium dioxide-alumina (HfO₂—Al₂O₃) alloy, other suitable high-k dielectric material, or combinations thereof. The gate dielectric layers 204/304 may be formed by any of the processes described herein, such as ALD, CVD, PVD, oxidation-based deposition process, other suitable process, or combinations thereof. In an embodiment, before forming the gate dielectric layers 204/304, interfacial layers 203/303 are formed on the channel layers 202/302. The interfacial layers 203/303 may be formed by thermal oxidation, chemical oxidation, ALD, CVD, or other suitable processes. The interfacial layers 203/303 may include a dielectric material, such as SiO₂, HfSiO, SiON, other silicon-containing dielectric material, other suitable dielectric material, or combinations thereof.

Still referring to FIG. 8, the CFET gate regions 108 are divided into gate regions 208 below the channel isolation layer 513 and gate regions 308 above the channel isolation layer 513. For purposes of description, the gate regions 208 are described as PFET gate regions 208, and the gate regions 308 are described as NFET gate regions 308. As such, the NFET gate regions 308 are vertically above the PFET gate regions 208 such that NFET devices are formed over PFET devices. However, the present disclosure is not limited thereto. In other embodiments, the PFET gate regions 208 may be above the NFET gate regions 308 such that PFET devices are formed over NFET devices.

Still referring to FIG. 8, the PFET gate regions 208 include interfacial layers 203 directly on top and bottom surfaces of the channel layers 202. The PFET gate regions further include gate dielectric layers 204 directly on top and bottom surfaces of the interfacial layers 203 and on side surfaces of the inner spacers 116. The NFET gate regions 308 include interfacial layers 303 directly on top and bottom surfaces of the channel layers 302. The NFET gate regions 308 further include gate dielectric layers 304 directly on top and bottom surfaces of the interfacial layers 303 and on side surfaces of the inner spacers 116 (and/or the gate spacers 111).

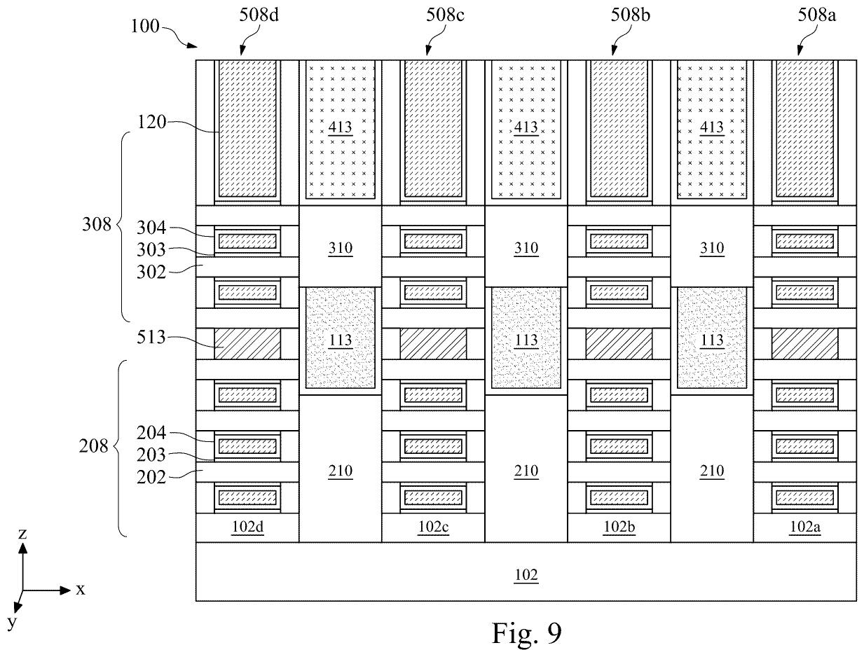

Now referring to FIG. 9, the method 1000 at operation 1026 deposits a gate metal 120 (also referred to as a metal gate electrode or a gate stack) over the first and second plurality of gate dielectric layers 204/304, thereby forming respective CFET metal gate structures 508a, 508b, 508c, and 508d. The gate metal 120 may include Ti, Ag, Al, TiAlN, TaC, TaCN, TaSiN, Mn, Zr, TiN, TaN, Ru, Mo, Al, WN, Cu, W, or any suitable materials. In an embodiment, a same gate metal 120 is deposited over both the PFET gate regions 208 and the NFET gate regions 308. In other embodiments, different metal materials are used for the PFET gate regions 208 and the NFET gate regions 308. The gate metal 120 may include a capping layer, a work function metal layer, and a filling metal layer. The capping layer may include titanium nitride, tantalum nitride, or other suitable material, formed by a proper deposition technique such as ALD. The filling metal layer may include aluminum, copper, silicide, suitable other metal, or metal alloy deposited physical vapor deposition (PVD) or other suitable deposition technology.

The work function metal layer includes a conductive layer of metal or metal alloy with proper work function such that the corresponding FET is enhanced for its device performance. The work function (WF) metal layer is different for a PFET and an NFET, respectively referred to as an n-type WF metal and a p-type WF metal. The choice of the WF metal depends on the FET to be formed on the active region. For example, an n-type WF metal is a metal having a first work function such that the threshold voltage of the associated NFET is reduced. For example, the n-type WF metal has a work function of about 4.2 eV or less. A p-type WF metal is a metal having a second work function such that the threshold voltage of the associated PFET is reduced. For example, the p-type work function metal has a WF of about 5.2 eV or higher. An n-type WF metal may comprise a metal with sufficiently low effective work function such as titanium, aluminum, tantalum carbide, tantalum carbide nitride, tantalum silicon nitride, or combinations thereof. A p-type WF metal may comprise a metal with a sufficiently large effective work function, such as titanium nitride, tantalum nitride, ruthenium, molybdenum, tungsten, platinum, or combinations thereof.

In some embodiments, instead of, or in addition to using work function metals to tune the respective n-type and p-type FETs, the filling metal themselves are n-and p-type specific. For example, a p-type gate metal 120 (which may include p-type work function or fill metals) is deposited over the PFET gate regions 208. The p-type gate metal 120 wraps around channels 202. And an n-type gate metal 120 (which may include n-type work function or fill metals) is deposited over the NFET gate regions 308. The n-type gate metal 120 wraps around channels 302. Note that in cases where the PFET and NFET gate regions 208 and 308 are flipped, respective p-type and n-type gate metals 120 are also flipped accordingly.

In some cases, it is desirable for the PFET and NFET to share a same gate contact. For example, in memory applications, it may be desirable to have gates of PFET and NFET devices connect to each other (e.g., gates of pull-up and pull-down transistors in SRAM devices are coupled to each other). In these cases, there is no gate isolation between the gate metals 120 in the PFET and NFET gate regions 208 and 308. As such, a same gate metal 120 may be continuously deposited in the gate regions 208 and gate regions 308. Alternatively, if gate is tuned between PFET and NFET, a first type (e.g., p-type) gate metal 120 is first deposited in the gate region 208, then a second type (e.g., n-type) gate metal 120 is deposited directly on the first type gate metal 120.

In many cases however, the PFET and NFET do not share a same gate contact. As such, proper gate isolation is necessary to isolate between the PFET and NFET gate regions 208 and 308. Turning now to FIGS. 10A-13A and 10B-13B, a process for forming a gate isolation feature 514 is described. The gate isolation feature 514 is configured to isolate adjacent gates and to prevent short and current leakage.

FIGS. 10A-13A illustrate cross-sectional views of a CFET gate region 108a cut along a length of a channel region 102a along the x direction. The CFET gate region 108a corresponds to the CFET gate region 108a in FIG. 9, and the corresponding features will not be described again for the sake of brevity. FIGS. 10B-13B illustrate cross-sectional views cut along a length of the CFET metal gate structure 508a along the y direction and across the CFET gate region 108a. Note that in the y cross-sectional views of FIGS. 10B, 11B, 12B, 13B, and 14B, an isolation structure 206 surrounds sidewalls of channel region 102a to isolate between adjacent active regions along the y direction. The isolation structure 206 may include silicon oxide, silicon nitride, silicon oxynitride, other suitable isolation material (for example, including silicon, oxygen, nitrogen, carbon, or other suitable isolation constituent), or combinations thereof. The isolation structure 206 can include different structures, such as shallow trench isolation (STI) structures and/or deep trench isolation (DTI) structures. The channel region 102a protrudes above a top surface of the isolation structure 206. Portions of the gate dielectric layer 204 may land on surfaces of the channel region 102a (and/or on an interfacial layer 203 over the channel region 102a). Portions of the gate dielectric layer 204 may also land on a top surface of the isolation structure 206.

Referring now to FIGS. 10A-10B, the method 1000 at operation 1026 deposits a first gate metal 120a over the first and second plurality of gate dielectric layers 204/304, thereby forming respective CFET metal gate structures (e.g., a CFET metal gate structure 508a). FIGS. 10A-10B may correspond to the workpiece described with respect to FIG. 9, except that gate metal 120 in FIG. 9 is deposited as a first gate metal 120a. The first gate metal 120a is deposited over the isolation structure 206 and surrounding sidewalls of the channel region 102a. In the present embodiment, the first gate metal 120a includes one or more metal gate layers (e.g., a capping layer, a work function metal layer, and a filling metal layer). In an embodiment, the first gate metal 120a includes a p-type work function and/or gate fill metal as described herein. The first gate metal 120a may be deposited by CVD, PVD, plating, and/or other suitable processes. The first gate metal 120a completely surrounds and fills in the gap between channels 202 and between channels 302. Along the y-z plane, the first gate metal 120a also surrounds sidewalls of the channel isolation layer 513. The channel isolation layer 513 may directly contact a bottom surface of the bottommost channel 302 and a topmost channel 202. The bottommost channel 302 and topmost channel 202 may each not be completely surrounded by interfacial layers 203/303 and/or gate dielectric layers 204/304 in the y-z plane. This may be due to the direct interface of the bottommost channel 302 and topmost channel 202 with the channel isolation layer 513.

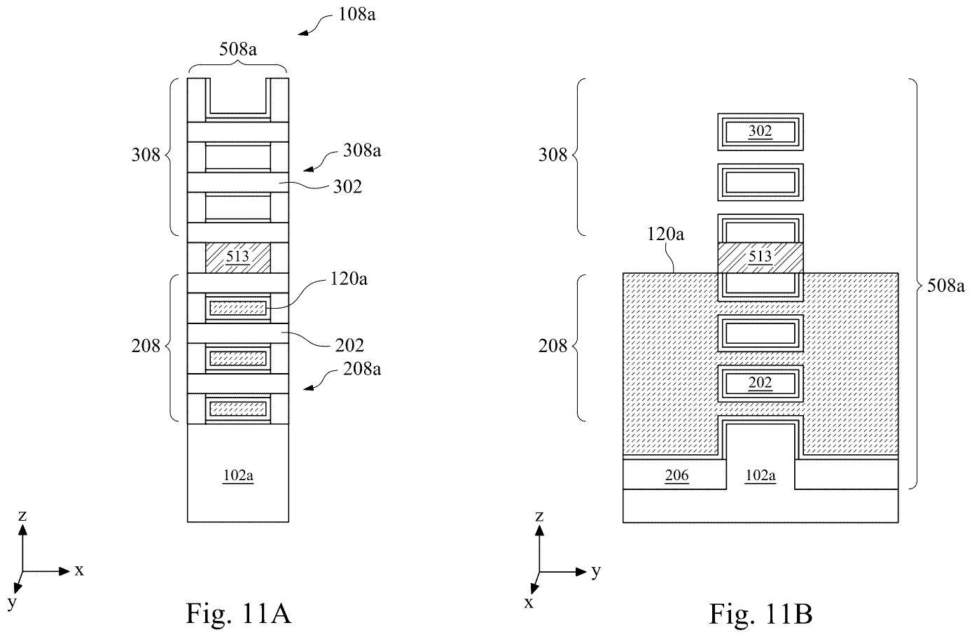

Now referring to FIGS. 11A-11B, the method 1000 at operation 1028 etches back the first gate metal 120a. The operation 1028 may include a controlled selective etching of the first gate metal 120a without substantially etching the channels 302, the interfacial layers 303, the gate dielectric layers 304, and the channel isolation layer 513. For example, as part of the etch-back process, an etchant selectivity may be selected such that metal is etched at a higher rate than dielectric. As shown in FIG. 11A, the operation 1028 removes the first gate metal 120a in the NFET gate region 308 while the first gate metal 120a remains in the PFET gate region 208. As shown in FIG. 11B, the operation 1028 partially or fully exposes side surfaces of the channel isolation layer 513. In at least one embodiment, the etch back causes a top surface of the first gate metal 120a to be substantially coplanar with a bottom surface of the channel isolation layer 513.

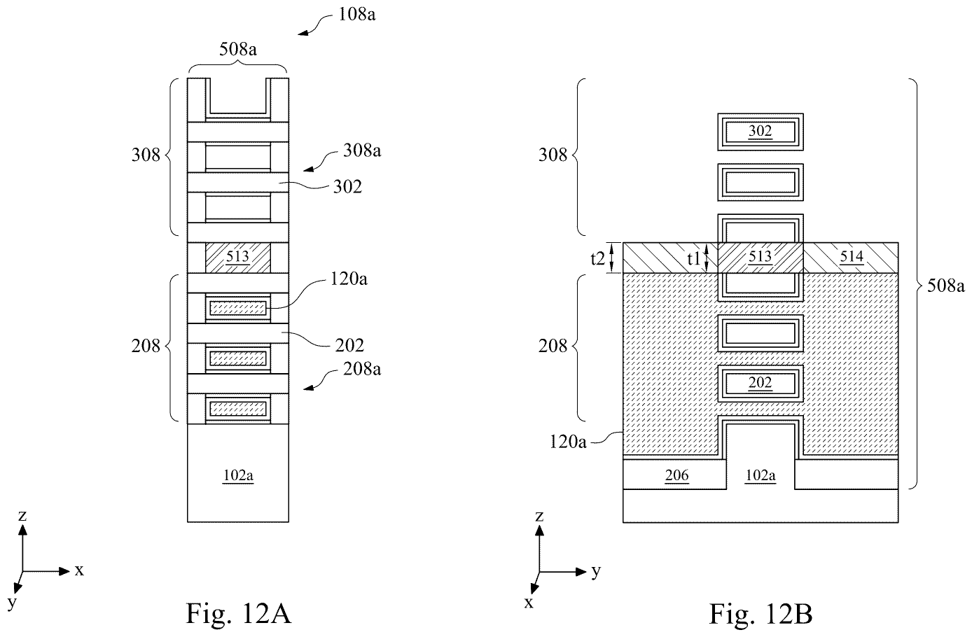

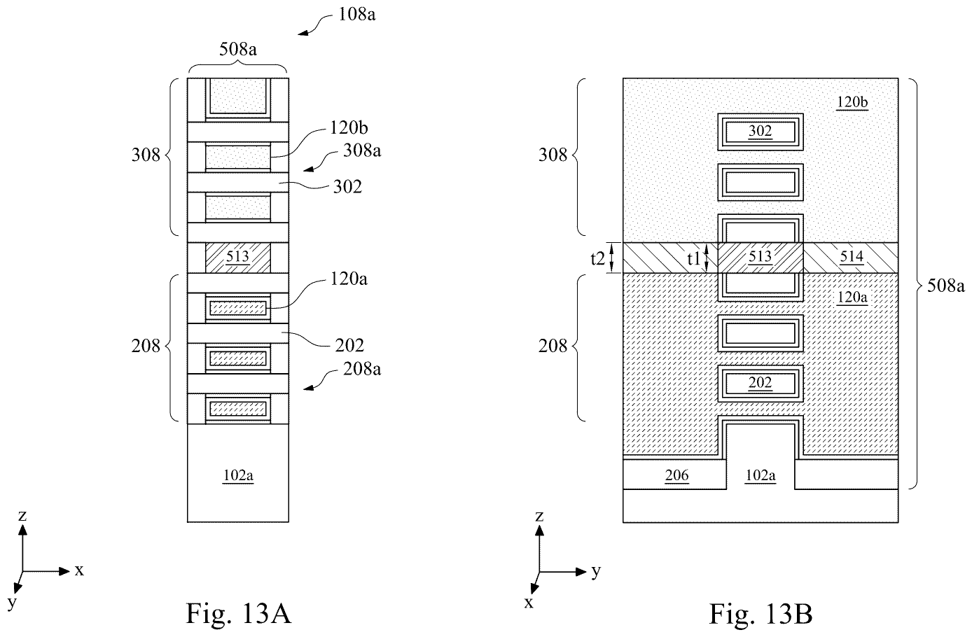

Now referring to FIGS. 12A-12B, the method 1000 at operation 1030 deposits a gate isolation feature 514 on the first gate metal 120a. The gate isolation feature 514 is configured to isolate the gate metal 120a in the PFET gate region 208 from the later-formed gate metal 120b in the NFET gate region 308. In an embodiment, the gate isolation feature is formed with a dielectric constant lower than commonly used Si-based material (e.g., SiO₂, SiCN, SiOCN, SiN or other materials having dielectric constant greater than these materials). In this embodiment, the low-k dielectric has a dielectric constant lower than 7 (e.g., lower than the dielectric constant for silicon nitride). In further embodiments, the gate isolation feature 514 is formed of a low-k dielectric having a dielectric constant lower than that of silicon oxide (e.g., <3.9). If a high-k dielectric material is used (e.g., silicon nitride, or other materials having a dielectric constant greater than that of silicon oxide), high capacitive coupling is induced between top and bottom gates, thereby degrading device performance. This issue is further exacerbated when a separation distance between the top and bottom gates is small (e.g., due to pitch size reduction), as in the case of CFETs. The separation distance may be defined by the thickness t1 of the channel isolation layer 513. In an embodiment, the thickness t1 spans an entire vertical spacing between the topmost channel 202 and the bottommost channel 302. In an embodiment, the thickness t1 is less than or equal to 10 nm, such as less than 5 nm. In the embodiment shown, the gate isolation feature 514 has a thickness t2, and the thickness t2 is same or substantially same as the thickness t1. In other words, the thickness of the channel isolation layer 513 may define the thickness of the gate isolation feature 514. However, in additional embodiments, the thickness t2 can be greater than or smaller than the thickness t1, as long as there is sufficient thickness for gate separation.

In an embodiment, the gate isolation feature 514 includes boron nitride (BN), which has a low dielectric constant (e.g., <3.9). In further embodiments, the gate isolation feature 514 may broadly include BN-based materials, such as amorphous BN, hexagonal BN, mix type BN, SiBN, BCN, SiBCN, or other combinations. Among these candidates, pure BN (e.g., aBN, hBN, mix type BN) exhibits the lowest k value. Boron nitride (or BN-based materials) is preferable over other low-k materials because it is more robust when applied to separating metal gates. For example, BN has an advantage over silicon-containing low-k materials (e.g., silica-based and/or silsesquioxane (SSQ)-based materials) by minimizing the presence of oxygen atoms. Excessive oxygen atoms may cause metal interdiffusion such that the later-formed second gate metal 120b may diffuse into the first gate metal 120a, or vice versa. Further, BN is more dense and less porous than many of the silicon-based low-k materials, thereby further avoiding metal diffusion caused by decreased material density, which could cause unwanted shorts or current leakage. Polymer-based materials is another type of material that can achieve low-k. Polymer-based materials are more dense and can reduce issues stemming from porosity. However, BN still has advantage over polymer-based materials due to having greater thermal and mechanical stability. In the application of separating metal gates, the low-k material must withstand temperatures used for interconnect manufacturing in back-end-of-line (BEOL) after forming the CFET metal gates. This may be an issue for certain organic polymers, as they begin to decompose at lower temperatures, restricting process windows and reducing the choice of polymers. In some silicon-based materials, elevated temperatures may also increase the k value of the material. Using boron nitride for gate isolation addresses these and other issues. This is due to boron nitrides'high density, lack of oxygen atoms, and its ability to be formed at low temperatures while providing high thermal stability. Although advantages of boron nitride is described, the present disclosure is not limited thereto. In some embodiments, silicon-containing and/or polymer-based low-k materials may still be used for reasons previously described (e.g., to reduce capacitive coupling and improve device performance).

As a CFET gate isolation material, the gate isolation feature 514 is grown in a particular ring structure for isolation and structural benefits described herein. For example, the gate isolation feature 514 includes boron nitride and is grown in a ring structure to form hexagonal boron nitride (h-BN). As compared with amorphous boron nitride (a-BN), h-BN has greater oxidation resistance and higher thermal conductivity. In an embodiment, the gate isolation feature 514 includes h-BN and has less than 4% oxygen concentration. In an embodiment, the gate isolation feature 514 includes h-BN and has an in-plane thermal conductivity above 390 W/m·K at room temperature. In an embodiment, the gate isolation feature 514 is grown as a h-BN layered structure in a crystalline form similar to graphite. As a comparison, amorphous BN (a-BN) is in a non-crystalline amorphous form and only exhibits an in-plane thermal conductivity around 3 W/m·K, which is not considered as a thermal conductive material in the context of the present disclosure. Further, h-BN is well suited for CFET gate isolation due to its ability to grow on metals at low temperatures. As described in further detail below, boron nitride may grow on the first gate metal 120a at temperatures ranging between about 200° C. to about 400° C. The combination of having low-k properties, oxidation resistance, high thermal conductivity, and low growth temperature allow superior gate isolation without issues of metal interdiffusion, metal oxidation, while providing a dense material for structural support and dissipating heat for thermal control.

The method 1000 at operation 1030 deposits the gate isolation feature 514 through atomic layer deposition (ALD) or chemical vapor deposition (CVD). In an ALD process, the gate isolation feature 514 is deposited by sequentially and recursively applying a first precursor and then a second precursor to form a thin film on the first gate metal 120a. The first precursor may be a metal-containing precursor and the second precursor may be an oxidant or reactant gas, or vice versa. Between applying the first and second precursors, a purge or evacuation step is performed to pump out gasses between each dose of the respective first and second precursors. In a CVD process, the first and the second precursors are applied simultaneously to form a thin film on the first gate metal 120a.

In an embodiment, the first precursor includes a ring structure precursor having boron and nitride, and the second precursor includes an N2 plasma, NH3 plasma, or a combination thereof. Applying the second precursor includes performing a plasma treatment by flowing charged ions that react with the first precursor. In an embodiment, the first precursor may be borazine (B₃H₆N₃), 1,3,5,-Trimethylborazine (C₃H₉B₃N₃), or a combination thereof. Using borazine (B₃H₆N₃) and/or 1,3,5,-Trimethylborazine (C₃H₉B₃N₃) as precursor allows the ALD/CVD process to perform at a relatively low temperature, such as between about 200° C. and about 400° C. This is mainly due to the existing B—N ring-like structure in borazine and 1,3,5,-Trimethylborazine. As a comparison, if the precursor uses a non-ring-containing molecule, such as borane (BH₃), the reaction temperature may have to be raised above 1000° C. However, BEOL process generally requires a processing temperature less than about 500° C., otherwise various layers in the workpiece (e.g., various ILD or low-k layers) may be damaged by the excessively high temperature above 500° C.

Now referring to FIGS. 13A-13B, the method 1000 at operation 1032 deposits a second gate metal 120b over the gate isolation feature 514 and over the second plurality of gate dielectric layers 304, thereby forming respective CFET metal gate structures (e.g., CFET metal gate structure 508a) having first gate metals 120a and second gate metals 120b surrounding channels 202 and 302, respectively. In the present embodiment, the second gate metal 120b includes one or more metal gate layers (e.g., a capping layer, a work function metal layer, and a filling metal layer). In an embodiment, the second gate metal 120b includes an n-type work function and/or gate fill metal as described herein. The second gate metal 120b may be deposited by CVD, PVD, plating, and/or other suitable processes. The second gate metal 120b completely surrounds and fills in the gap between channels 302.

Additional operations can be provided before, during, and after method 1000, and some of the operations described can be moved, replaced, or eliminated for additional embodiments of method 1000. Additional operations may include forming device-level contacts connecting to S/D features 210/310 and/or the metal gates of the CFET metal gate structure 508a-508d. Additional operations may further include forming interconnect structures over the device-level contacts. The interconnect structures may include one or more interconnect layers with wires and vias embedded in dielectric layers. The one or more interconnect layers connecting gate, source, and drain electrodes of various transistors, as well as other circuits in the device 100, to form an integrated circuit in part or in whole. Additional operations may further include forming passivation layer(s) over the interconnect layers.

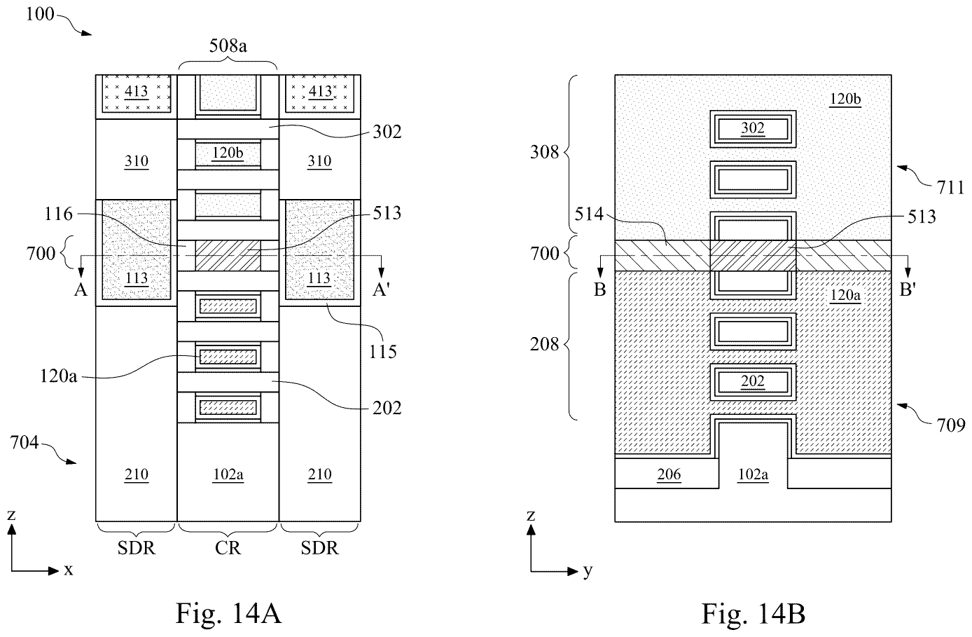

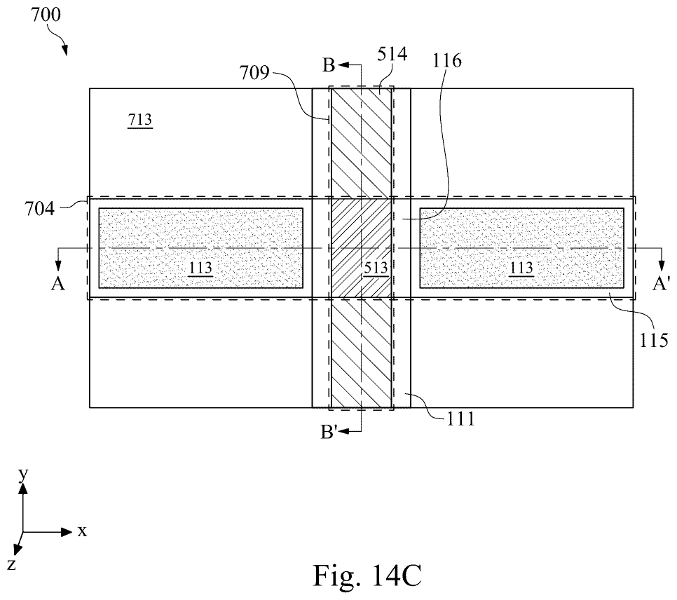

FIGS. 14A-14C illustrate various views of a device isolation layer 700 vertically disposed between an NFET and a PFET of a CFET semiconductor device 100. As shown in FIGS. 14A and 14B, the device isolation layer 700 cuts along the channel isolation layer 513 in both the x and y direction. The device isolation layer 700 cuts along the line A-A′ in FIG. 14A and the line B-B′ in FIG. 14B.

Referring to FIG. 14A, the device isolation layer 700 includes the etch stop layer 115, the S/D isolation layer 113, the inner spacers 116, and the channel isolation layer 513. Referring to FIG. 14B, the device isolation layer 700 includes the gate isolation feature 514 and the channel isolation layer 513. In an embodiment, the S/D isolation layers 113 and channel isolation layer 513 include a different dielectric material than that of the gate isolation feature 514. This is because the S/D isolation layers 113 and channel isolation layer 513 is configured to separate semiconductor material (e.g., silicon, silicon germanium, etc.) while the gate isolation feature 514 is configured to separate metal. Issues described herein regarding separating metals may not apply to separating semiconductor material, and so the dielectric materials used for S/D and channel isolation is not as restricted. In an embodiment, the S/D isolation layers 113 and channel isolation layer 513 may include an oxide-based dielectric while the gate isolation feature 514 includes boron nitride. In a further embodiment, the etch stop layer 115 and inner spacers 116 include a silicon nitride-based dielectric.

As shown in FIG. 14A, the CFET device 100 includes an active region 704 having a channel region CR and S/D regions adjacent the channel region CR. The channel region CR may include the channel region 102a sandwiched between S/D features 210 over the S/D regions SDR. A lower stack of channels 202 may be disposed over the channel region 102a. The CFET device 100 further includes the S/D isolation layers 113 over the S/D features 210, and the channel isolation layer 513 over the lower stack of channels 202. The CFET device 100 further includes S/D features 310 over the S/D isolation layers 113, and an upper stack of channels 302 over the channel isolation layer 513. The lower stack of channels 202 may be wrapped around by the first gate metal 120a and the upper stack of channels 302 may be wrapped around by the second gate metal 120b.

As shown in FIG. 14B, the CFET device 100 includes a lower gate stack 709 (e.g., having the first gate metal 120a) over the isolation structure 206. The lower gate stack 709 surrounds the channel region 102a and the channels 202 over the channel region 102a. The CFET device 100 further includes an upper gate stack 711 (e.g., having the second gate metal 120b). The upper gate stack 711 surrounds the channels 302. The lower gate stack 709 and the upper gate stack 711 are separated from each other by the gate isolation feature 514 of the device isolation layer 700.

FIG. 14C shows a top view of the device isolation layer 700 cut along an x-y plane across the lines A-A′ and B-B′ shown in FIGS. 14A and 14B. As shown in FIG. 14C, the device isolation layer 700 is disposed over an underlying active region 704 denoted by a dashed box extending in the x direction. The device isolation layer 700 is further disposed over an underlying lower gate stack 709 denoted by a dashed box extending in the y direction. The underlying lower gate stack 709 is disposed over the channel region 102a of the underlying active region 704 (see FIG. 14B for reference).

Still referring to FIG. 14C, along the length of the active region 704, the device isolation layer 700 includes S/D isolation layers 113 and etch stop layers 115 disposed over the S/D features 210. The etch stop layers 115 may act as barrier liners that surround the S/D isolation layers 113. Also along the length of the active region 704, the device isolation layer 700 further includes the channel isolation layer 513 sandwiched by inner spacers 116 over the lower stack of channels 202. The inner spacers 116 may directly interface with the etch stop layers 115.

Still referring to FIG. 14C, along the length of the lower gate stack 709, the device isolation layer 700 includes the gate isolation feature 514 disposed over the lower gate stack 709 and the gate spacers 111 disposed along sidewalls of the gate isolation feature 514. As previously described, the gate spacers 111 are formed when forming the dummy gate structures 110. Also along the length of the lower gate stack 709, the device isolation layer 700 further includes the channel isolation layer 513 and the inner spacers 116 disposed along sidewalls of the channel isolation layer 513.

Still referring to FIG. 14C, an interlayer dielectric (ILD) layer 713 may interface the gate spacers 111 along the x direction and the etch stop layers 115 along the y direction. The ILD layer 713 may include one or more dielectric materials. For example, the ILD layer 713 includes a dielectric material including, for example, silicon oxide, silicon nitride, silicon oxynitride, TEOS formed oxide, PSG, BPSG, low-k dielectric material, other suitable dielectric material, or combinations thereof. Exemplary low-k dielectric materials include silicon or polymer-based materials such as FSG, carbon doped silicon oxide, Black Diamond® (Applied Materials of Santa Clara, California), Xerogel, Aerogel, amorphous fluorinated carbon, Parylene, BCB, SiLK (Dow Chemical, Midland, Michigan), polyimide, or combinations thereof. In an embodiment, the ILD layer 713, the S/D isolation layers 113, and the channel isolation layer 513 each include a same or similar material (e.g., silicon oxide, or a silicon-based low-k material), while the gate isolation feature 514 includes boron nitride. In an embodiment, the inner spacers 116 include a different material than that of the channel isolation layer 513 for etchant selectivity. In an embodiment, the gate spacers 111 include a different material than that of the gate isolation feature 514 for etchant selectivity. In an embodiment, the gate spacers 111 include a different material than that of the inner spacers 116 for etchant selectivity.

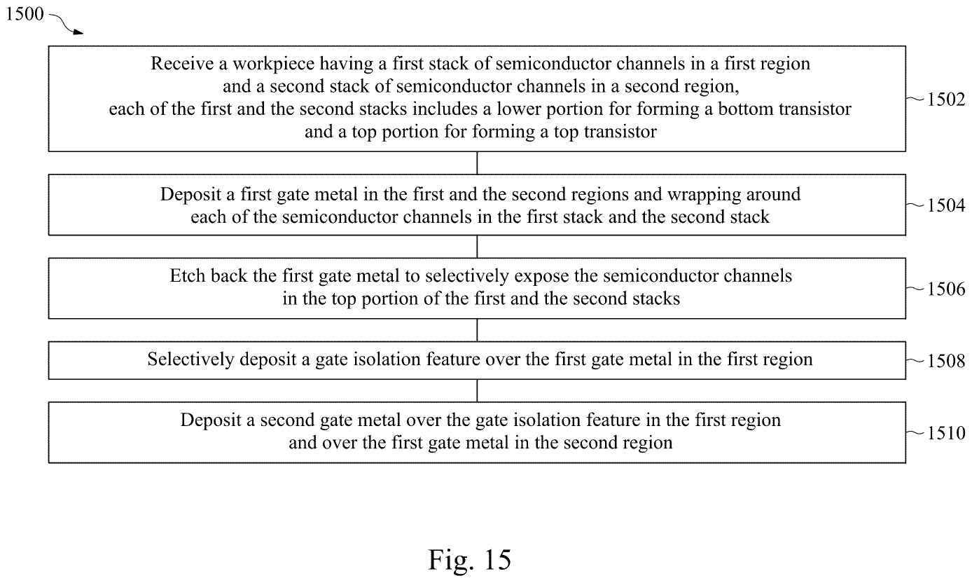

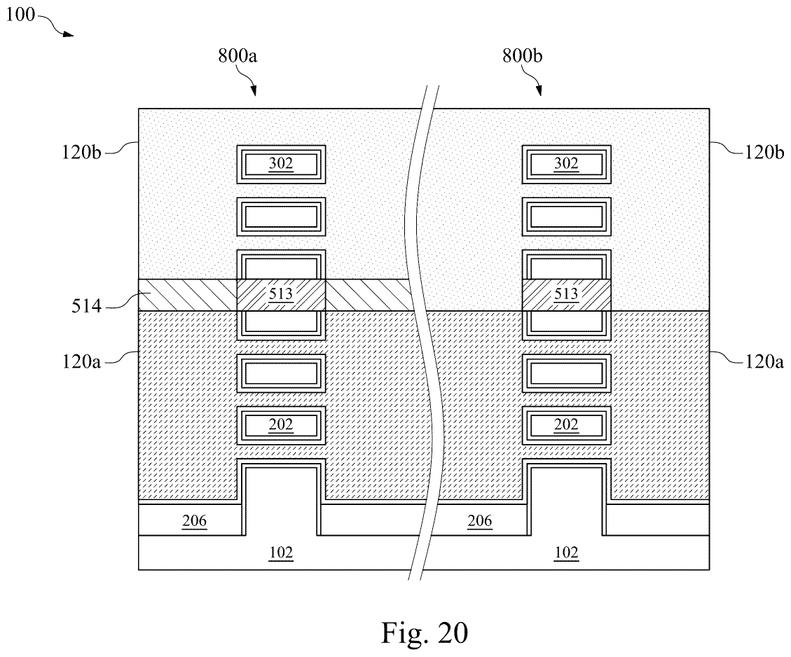

FIG. 15 is a flow chart of a method 1500 to form a CFET semiconductor device 100 having a gate isolation feature 514, in portion or in entirety, according to another embodiment of the present disclosure. FIGS. 16-20 illustrate cross-sectional views of a CFET semiconductor device 100 having a gate isolation feature 514, at intermediate stages of fabrication and processed in accordance with the method 1500 of FIG. 15. The method 1500 is similar to the method 1000. The difference is that the gate isolation feature 514 is selectively formed in a first region 800a requiring gate isolation, while a second region 800b requiring shared gates is free of the gate isolation feature 514. The method 1500 is described with reference to FIGS. 16-20. For the sake of brevity, similar features described with respect to the method 1000 will not be repeated again when describing the method 1500.

Referring now to FIG. 16, the method 1500 at operation 1502 receives a workpiece for forming a CFET semiconductor device 100. The work piece includes a first stack of semiconductor channels 202/302 in a first region 800a and a second stack of semiconductor channels 202/302 in a second region 800b. The first and second stacks are formed on a same substrate 102, and they are isolated from each other by the isolation structure 206. Each of the first and the second stacks includes a lower portion for forming a bottom transistor (e.g., a PFET) and a top portion for forming a top transistor (e.g., an NFET). In each of the first and second stacks, the semiconductor channels 202 are separated from the semiconductor channels 302 by a channel isolation layer 513.

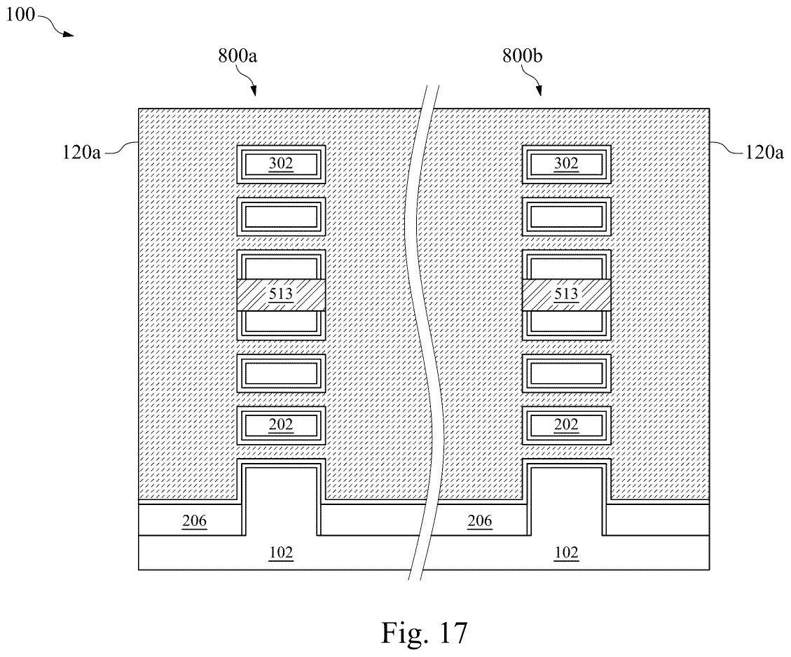

Referring now to FIG. 17, the method 1500 at operation 1504 deposits a first gate metal 120a in the first and the second regions 800a and 800b and wrapping around each of the semiconductor channels 202/302 in the first stack and the second stack. The first gate metal 120a is disposed over the isolation structure 206 and also interfaces sidewalls of each channel isolation layer 513 in the first and the second stacks.

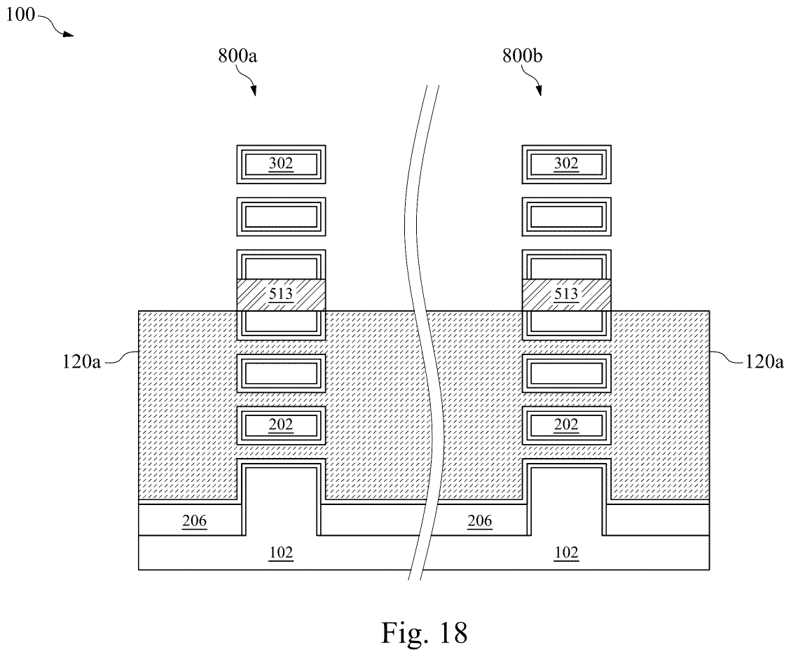

Referring now to FIG. 18, the method 1500 at operation 1506 etches back the first gate metal 120a to selectively expose the semiconductor channels 302 in the top portion of the first and the second stacks. After operation 1506, sidewalls of each channel isolation layer 513 in the first and the second stacks are also exposed.

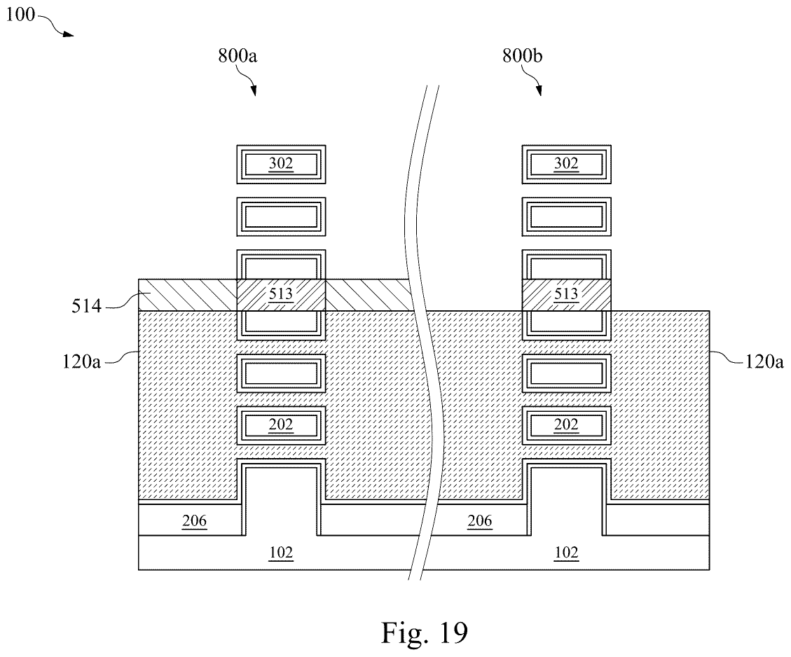

Referring now to FIG. 19, the method 1500 at operation 1508 selectively deposits a gate isolation feature 514 over the first gate metal 120a in the first region 800a but not in the second region 800b. For example, the gate isolation feature 514 is first deposited in both the first and the second regions 800a and 800b. Then, a lithography process is performed to form a patterned mask layer that covers the first region 800a while exposing the second region 800b. Then, an etching process is performed using the patterned mask layer as an etch mask. The etching process etches away the first gate metal 120a in the second region 800b. Thereafter, the patterned hard mask layer is removed by any suitable process.

Referring now to FIG. 19, the method 1500 at operation 1510 deposits a second gate metal 120b over the gate isolation feature 514 in the first region 800a and over the first gate metal 120a in the second region 800b. The second gate metal 120b wraps around each of the semiconductor channels 302 in the first stack and the second stack.

Additional operations can be provided before, during, and after method 1500, and some of the operations described can be moved, replaced, or eliminated for additional embodiments of method 1500. Additional operations may include forming device-level contacts connecting to S/D features 210/310 and/or to metal gates of the CFET metal gate structures 508a-508d. Additional operations may further include forming interconnect structures over the device-level contacts. The interconnect structures may include one or more interconnect layers with wires and vias embedded in dielectric layers. The one or more interconnect layers connecting gate, source, and drain electrodes of various transistors, as well as other circuits in the device 100, to form an integrated circuit in part or in whole. Additional operations may further include forming passivation layer(s) over the interconnect layers.

The embodiments described thus far illustrate CFET structures having a PFET over an NFET. Note that the embodiments of this disclosure can equally apply to other types of CFET and/or stacked transistor configurations. For example, the present disclosure may apply to a PFET over an NFET (as described herein), an NFET over a PFET, a PFET over a PFET, and an NFET over an NFET.

Although not limiting, the present disclosure offers advantages for isolating gates between a top and a bottom transistor (e.g., in a CFET device). One example advantage is using a low-k dielectric for reducing capacitive coupling. Another example advantage is using boron nitride for its robust properties compared to other types of low-k materials. Another example advantage is forming hexagonal boron nitride for its superior oxidation resistance and thermal conductivity. Another example advantage is incorporating the gate isolation feature with other device isolation features in a same device isolation layer. Another example advantage is selectively forming the gate isolation feature.

One aspect of the present disclosure pertains to a method of forming a semiconductor device. The method includes forming a structure having a bottom region and a top region, the bottom region having a first plurality of channels for forming a first type transistor, the top region having a second plurality of channels for forming a second type transistor, where the top and the bottom regions are separated by a channel isolation layer; depositing a first gate metal over the structure and wrapping around each channel of the first and the second plurality of channels; etching back the first gate metal to expose each channel of the second plurality of channels; depositing a gate isolation layer on the etched-back first gate metal, where the gate isolation layer has a dielectric constant lower than 7; and depositing a second gate metal on the gate isolation layer and wrapping around each channel of the second plurality of channels.

In an embodiment, the gate isolation layer is a low-k gate dielectric having a dielectric constant lower than 4. In an embodiment, the gate isolation layer includes amorphous boron nitride (BN), hexagonal BN, SiBN, BCN, SiBCN, or combinations thereof.

In an embodiment, the depositing of the gate isolation layer includes applying a first precursor gas and a second precursor gas, the first precursor gas includes a ring structure precursor having boron and nitride, and the second precursor gas includes an N2 plasma, NH3 plasma, or a combination thereof. In a further embodiment, the first precursor gas includes borazine (B3H6N3), 1,3,5,-Trimethylborazine (C3H9B3N3), or a combination thereof. In a further embodiment, the first and the second precursors are applied recursively through atomic layer deposition (ALD). In a different embodiment, the first and the second precursors are applied simultaneously through chemical vapor deposition (CVD).

In an embodiment, the etching back of the first gate metal exposes side surfaces of the channel isolation layer. In an embodiment, the gate isolation layer is deposited adjacent to and surrounding the channel isolation layer. In an embodiment, the first gate metal has a higher work function than that of the second gate metal.

Another aspect of the present disclosure pertains to a method of forming a semiconductor device. The method includes forming a structure having a bottom region and a top region, the bottom region having a first plurality of channels for forming a first type transistor, the top region having a second plurality of channels for forming a second type transistor, where the top and the bottom regions are separated by a channel isolation layer; depositing a first gate metal over the structure and wrapping around each channel of the first and the second plurality of channels; etching back the first gate metal to expose each channel of the second plurality of channels; depositing a gate isolation layer on the etched-back first gate metal, where the gate isolation layer includes amorphous boron nitride (BN), hexagonal BN, SiBN, BCN, SiBCN, or combinations thereof; and depositing a second gate metal on the gate isolation layer and wrapping around each channel of the second plurality of channels.

In an embodiment, the second gate metal has a higher work function than that of the first gate metal. In an embodiment, the gate isolation layer has a dielectric constant lower than 4.

In an embodiment, the depositing of the gate isolation layer includes applying a first precursor gas and a second precursor gas, the first precursor gas includes a ring structure precursor having boron and nitride, and the second precursor gas includes an N2 plasma, NH3 plasma, or a combination thereof. In a further embodiment, the first precursor gas includes borazine (B3H6N3), 1,3,5,-Trimethylborazine (C3H9B3N3), or a combination thereof.

In an embodiment, the gate isolation layer is deposited adjacent to and surrounding the channel isolation layer, where the channel isolation layer and the gate isolation layer have a same or substantially same thickness.

Another aspect of the present disclosure pertains to a semiconductor device. The semiconductor device includes a first stack of semiconductor channels over a substrate; a first gate metal over the substrate and wrapping around the first stack of semiconductor channels; a channel isolation layer over a topmost semiconductor channel of the first stack of semiconductor channels; a gate isolation layer adjacent the channel isolation layer and over the first gate metal; a second stack of semiconductor channels over the channel isolation layer; and a second gate metal over the gate isolation layer and wrapping around the second stack of semiconductor channels. The gate isolation layer has a dielectric constant lower than 7 and is disposed vertically between the first gate metal and the second gate metal.

In an embodiment, the gate isolation layer includes boron nitride. In a further embodiment, the gate isolation layer includes hexagonal boron nitride (h-BN).

In an embodiment, the channel isolation layer and the gate isolation layer include different dielectric materials.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A method of forming a semiconductor device, comprising:
forming a structure having a bottom region and a top region, the bottom region having a first plurality of channels for forming a first type transistor, the top region having a second plurality of channels for forming a second type transistor, wherein the top and the bottom regions are separated by a channel isolation layer;
depositing a first gate metal over the structure and wrapping around each channel of the first and the second plurality of channels;
etching back the first gate metal to expose each channel of the second plurality of channels;
depositing a gate isolation layer on the etched-back first gate metal, wherein the gate isolation layer has a dielectric constant lower than 7; and
depositing a second gate metal on the gate isolation layer and wrapping around each channel of the second plurality of channels.

2. The method of claim 1, wherein the gate isolation layer is a low-k gate dielectric having a dielectric constant lower than 4.

3. The method of claim 1, wherein the gate isolation layer includes amorphous boron nitride (BN), hexagonal BN, SiBN, BCN, SiBCN, or combinations thereof.

4. The method of claim 1, wherein the depositing of the gate isolation layer includes applying a first precursor gas and a second precursor gas, the first precursor gas includes a ring structure precursor having boron and nitride, and the second precursor gas includes an N2 plasma, NH3 plasma, or a combination thereof.

5. The method of claim 4, wherein the first precursor gas includes borazine (B3H6N3), 1,3,5,-Trimethylborazine (C3H9B3N3), or a combination thereof.

6. The method of claim 4, wherein the first and the second precursors are applied recursively through atomic layer deposition (ALD).

7. The method of claim 4, wherein the first and the second precursors are applied simultaneously through chemical vapor deposition (CVD).

8. The method of claim 1, wherein the etching back of the first gate metal exposes side surfaces of the channel isolation layer.

9. The method of claim 1, wherein the gate isolation layer is deposited adjacent to and surrounding the channel isolation layer.

10. The method of claim 1, wherein the first gate metal has a higher work function than that of the second gate metal.

11. A method of forming a semiconductor device, comprising:
forming a structure having a bottom region and a top region, the bottom region having a first plurality of channels for forming a first type transistor, the top region having a second plurality of channels for forming a second type transistor, wherein the top and the bottom regions are separated by a channel isolation layer;
depositing a first gate metal over the structure and wrapping around each channel of the first and the second plurality of channels;
etching back the first gate metal to expose each channel of the second plurality of channels;
depositing a gate isolation layer on the etched-back first gate metal, wherein the gate isolation layer includes amorphous boron nitride (BN), hexagonal BN, SiBN, BCN, SiBCN, or combinations thereof; and
depositing a second gate metal on the gate isolation layer and wrapping around each channel of the second plurality of channels.

12. The method of claim 11, wherein the second gate metal has a higher work function than that of the first gate metal.

13. The method of claim 11, wherein the gate isolation layer has a dielectric constant lower than 4.

14. The method of claim 11, wherein the depositing of the gate isolation layer includes applying a first precursor gas and a second precursor gas, the first precursor gas includes a ring structure precursor having boron and nitride, and the second precursor gas includes an N2 plasma, NH3 plasma, or a combination thereof.

15. The method of claim 14, wherein the first precursor gas includes borazine (B3H6N3), 1,3,5,-Trimethylborazine (C3H9B3N3), or a combination thereof.

16. The method of claim 11, wherein the gate isolation layer is deposited adjacent to and surrounding the channel isolation layer, wherein the channel isolation layer and the gate isolation layer have a same or substantially same thickness.

17. A semiconductor device, comprising:
a first stack of semiconductor channels over a substrate;
a first gate metal over the substrate and wrapping around the first stack of semiconductor channels;
a channel isolation layer over a topmost semiconductor channel of the first stack of semiconductor channels;
a gate isolation layer adjacent the channel isolation layer and over the first gate metal;
a second stack of semiconductor channels over the channel isolation layer; and
a second gate metal over the gate isolation layer and wrapping around the second stack of semiconductor channels,
wherein the gate isolation layer has a dielectric constant lower than 7 and is disposed vertically between the first gate metal and the second gate metal.

18. The semiconductor device of claim 17, wherein the gate isolation layer includes boron nitride.

19. The semiconductor device of claim 18, wherein the gate isolation layer includes hexagonal boron nitride (h-BN).

20. The semiconductor device of claim 17, wherein the channel isolation layer and the gate isolation layer include different dielectric materials.
